(19) United States
(12) Patent Application Publication
(10) Pub. No.: US 2016/0276520 A1
(43) Pub. Date: Sep. 22, 2016

(54) THERMALLY-ASSISTED COLD-WELD BONDING FOR EPITAXIAL LIFT-OFF PROCESS

(71) Applicant: THE REGENTS OF THE UNIVERSITY OF MICHIGAN, Ann Arbor, MI (US)

(72) Inventors: Stephen R. Forrest, Ann Arbor, MI (US); Kyusang Lee, Ann Arbor, MI (US)

(21) Appl. No.: 15/034,310

(22) PCT Filed: Nov. 11, 2014
(86) PCT No.: PCT/US2014/065003

§ 371 Date: May 4, 2016

Related U.S. Application Data
(60) Provisional application No. 61/902,775, filed on Nov. 11, 2013.

(51) Int. Cl. H01L 31/18

(52) U.S. Cl. CPC H01L 31/1864; H01L 31/1896

(57) ABSTRACT

A process for assembling a thin-film optoelectronic device is disclosed. The process may include providing a growth structure comprising a wafer having a growing surface, a sacrificial layer, and a device region. The process may further include providing a host substrate and depositing a first metal layer on the device region and depositing a second metal layer on the host substrate. The process may further include bonding the first metal layer to the second metal layer by pressing the first and second metal layers together at a bonding temperature, wherein the bonding temperature is above room temperature and below the lower of a glass transition temperature of the host substrate and a melting temperature of the host substrate.

### CROSS-REFERENCE TO RELATED APPLICATION

This application claims the benefit of U.S. Provisional Application No. 61/902,775 filed Nov. 11, 2013, which is incorporated herein by reference in its entirety.

### STATEMENT REGARDING FEDERALLY SPONSORED RESEARCH

This invention was made with U.S. Government support under Contract No. W911 NF awarded by the U.S. Army Research Laboratory. The government has certain rights in the invention.

### JOINT RESEARCH AGREEMENT

The subject matter of the present disclosure was made by, on behalf of, and/or in connection with one or more of the following parties to a joint university-corporation research agreement: The Regents of the University of Michigan and NanoFlex Power Corporation. The agreement was in effect on and before the date the subject matter of the present disclosure was prepared, and was made as a result of activities undertaken within the scope of the agreement.

The present disclosure generally relates to a bonding process for thin-film devices and, in particular, to a thermally-assisted cold-weld bonding process.

Thin-film technologies, such as single-crystalline semiconductor-based devices, are desirable in the field of electronics due to their flexibility, light weight, and high performance characteristics. Unlike thin-film fabrication processes based on solution and deposition techniques, such as chemical vapor deposition (CVD), sputtering, and evaporation, which form an active region directly on a host substrate, thin-film peel off methods, such as epitaxial lift-off (ELO), spalling, and exfoliation, require a bonding process to transfer the thin active region to the handle or flexible host substrate.

In conventional ELO processes, lifted-off layers are typically attached to flexible secondary handles using adhesives, such as thermal releasing tape, wax, or glue. These adhesives can be bulky, heavy, brittle, and subject to degradation while also requiring an additional transfer following the separation of the epitaxy onto an intermediate handle. To eliminate all use of adhesives and the necessity of an intermediate handle transfer, bonding processes that directly attach the epitaxial surface to the final flexible substrate following layer grown have been developed

Certain direct-attachment bonding processes have involved adding metal layers to adjoining surfaces of the active region and the flexible host substrate and using cold-welding to bond them. Cold-weld bonding processes typically include pressing two surfaces together at a relatively high pressure (e.g., 50 MPa) at room temperature to achieve a uniformly bonded interface. At such high pressure, cold-weld bonding may damage the semiconductor wafer if the pressing force is non-uniform or if the device has an unexpected feature or defect, such as a point defect, dislocation, or piece of dust on a joining surface. Damage to devices may reduce fabrication rates and prevent wafer reuse.

Alternative direct-attachment bonding processes include thermocompression bonding, which typically involves the application of a lower pressure but at a high temperature (i.e., higher than the metal re-crystallization temperature). However, typical flexible substrates have a glass transition and/or a melting temperature below the re-crystallization temperature of metal layers commonly used in direct-attachment bonding processes. At such high temperatures, a flexible substrate may deform or become molten and separate from its metal layer. High amounts of stress can also be induced at high temperatures due to differing coefficients of thermal expansion between the semiconductor materials and the flexible substrate.

Disclosed herein is a particularly promising direct-attachment technique for bonding metal layers associated with an ELO process. Specifically, there is disclosed a thermally-assisted cold-weld bonding process using a lower pressure than typical cold-welding processes and a lower temperature than typical thermocompression bonding processes. Particularly, thermally-assisted cold-welding may reduce the likelihood of damaging semiconductor wafers, thereby increasing the reuse rate of the wafers for growing additional active regions. To realize the benefits of this process, the present inventors have identified thermally assisted cold-welding parameters that reduce damage to growth structures caused by pressure and heat.

Thus, disclosed herein is a process for assembling a thin-film optoelectronic device, wherein the process may include bonding an active region grown on a wafer to a flexible substrate using a thermally-assisted cold-weld bonding process above room temperature and below a glass transition temperature or a melting temperature of the flexible substrate. The bonding process may also use a lower pressure than typical cold-welding processes, thereby reducing damage to the growth structure and/or the host substrate.

In one aspect, the present disclosure includes a process for assembling a thin-film optoelectronic device. The process may include providing a growth structure comprising a wafer having a growing surface, a sacrificial layer, and a device region, wherein the sacrificial layer is disposed between the wafer and the device region, and wherein the device region has a surface furthest from the wafer. The process may further include providing a host substrate, wherein the host substrate comprises a polymer material. The process may further include depositing a first metal layer on the surface of the device region and depositing a second metal layer on the host substrate. The process may further include bonding the first metal layer to the second metal layer by pressing the first and second metal layers together at a bonding temperature, wherein the bonding temperature is above room temperature and below the lower of a glass transition temperature of the host substrate and a melting temperature of the host substrate.

In another aspect, the present disclosure includes a process for assembling a thin-film optoelectronic device. The process may include providing a growth structure comprising a wafer having a growing surface, a sacrificial layer, and a device region, wherein the sacrificial layer is disposed between the wafer and the device region, and wherein the device region has a surface furthest from the wafer. The process may further include providing a host substrate, wherein the host substrate comprises a metal foil. The process may further include depositing a first metal layer on the surface of the device region and depositing a second metal layer on the host substrate. The process may further include bonding the first metal layer to the second metal layer by pressing the first and second metal layers together at a bonding temperature, wherein the bonding temperature is above room temperature and below a melting temperature of the host substrate.

The accompanying figures are incorporated in, and constitute a part of this specification.

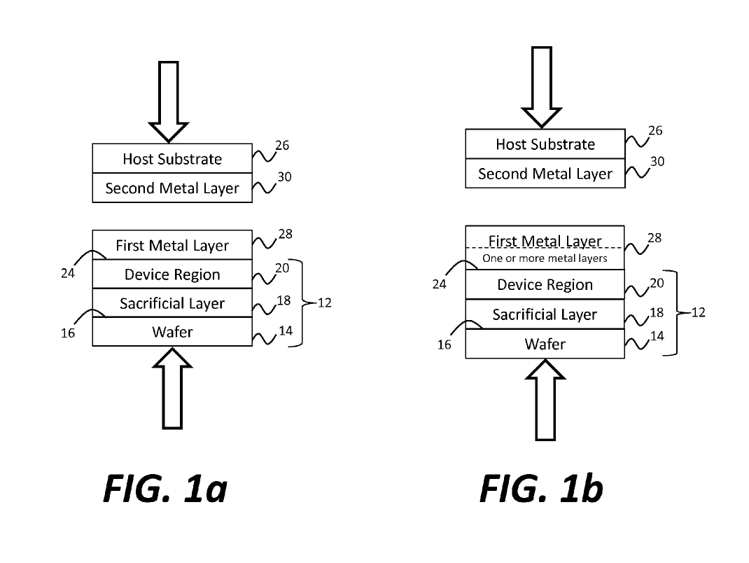

FIGS. 1a-b show schematics of exemplary growth structure and host substrate samples for performing the methods disclosed herein.

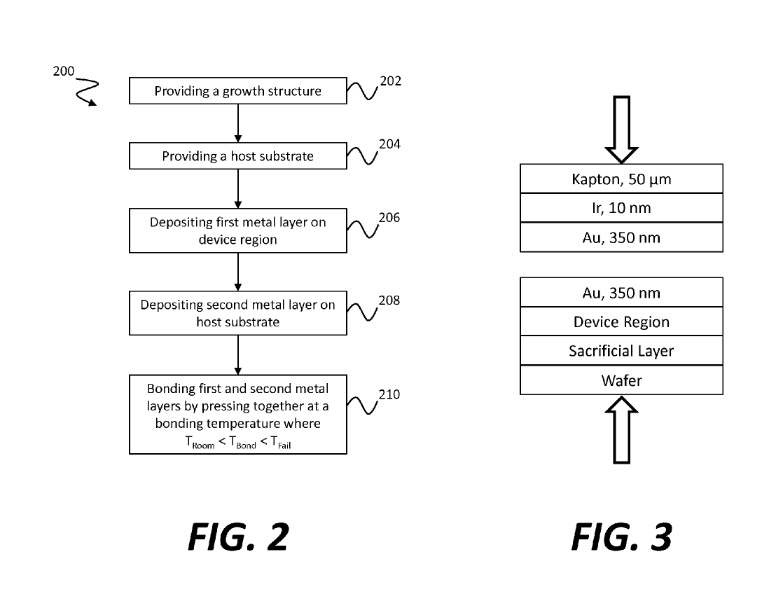

FIG. 2 shows a flow chart of an exemplary process according to the present disclosure.

FIG. 3 shows a schematic of an exemplary growth structure and host substrate for performing the disclosed methods.

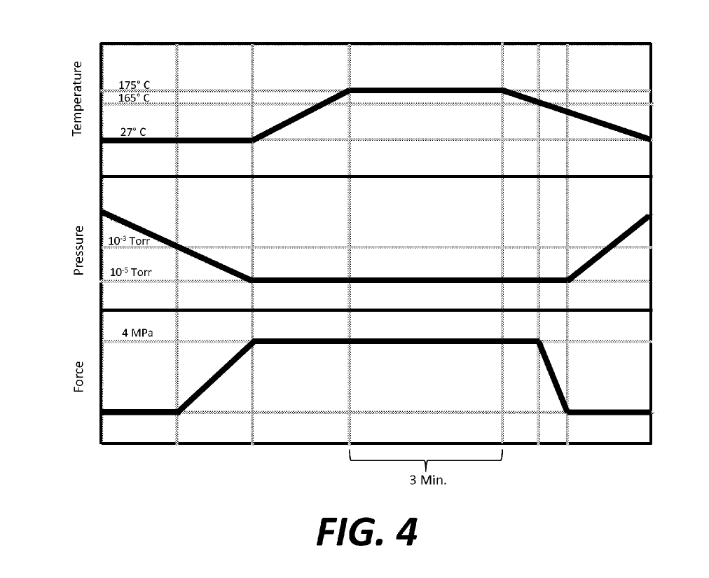

FIG. 4 shows a graph of exemplary force, pressure, and temperature profiles with respect to time that may be used with the exemplary process of FIG. 2.

As used herein, the term “III-V material,” may be used to refer to compound crystals containing elements from group IIIA and group VA of the periodic table. More specifically, the term “III-V material” may be used herein to refer to compounds which are combinations of the group of Gallium (Ga), Indium (In) and Aluminum (Al), and the group of Arsenic (As), Phosphorous (P), Nitrogen (N), and Antimony (Sb).

It should be noted that the III-V compounds herein are named in an abbreviated format. A two component material is considered to be in approximately a 1:1 molar ratio of group III:V compounds. In a three or more component system (e.g. InGaAlAsP), the sum of the group III species (i.e. In, Ga, and Al) is approximately 1 and the sum of the group V components (i.e. As, and P) is approximately 1, and thus the ratio of group III to group V is approximately unity.

Names of III-V compounds are assumed to be in the stoichiometric ratio needed to achieve lattice matching or lattice mismatching (strain), as inferred from the surrounding text. Additionally, names can be transposed to some degree. For example, AlGaAs and GaAlAs are the same material.

As used and depicted herein, a “layer” refers to a member or component of a device whose primary dimension is X-Y, i.e., along its length and width. It should be understood that the term layer is not necessarily limited to single layers or sheets of materials. In addition, it should be understood that the surfaces of certain layers, including the interface(s) of such layers with other material(s) or layers(s), may be imperfect, wherein said surfaces represent an interpenetrating, entangled or convoluted network with other material(s) or layer(s). Similarly, it should also be understood that a layer may be discontinuous, such that the continuity of said layer along the X-Y dimension may be disturbed or otherwise interrupted by other layer(s) or material(s).

Herein the term “semiconductor” denotes materials which can conduct electricity when charge carriers are induced by thermal or electromagnetic excitation. The term “photoconductive” generally relates to the process in which electromagnetic radiant energy is absorbed and thereby converted to excitation energy of electric charge carriers so that the carriers can conduct, i.e., transport, electric charge in a material. The terms “photoconductor” and “photoconductive material” are used herein to refer to semiconductor materials which are chosen for their property of absorbing electromagnetic radiation to generate electric charge carriers.

As described above, in one aspect, the present disclosure includes a process for assembling a thin film optoelectronic device using a thermally-assisted cold-weld bonding process. The process may reduce damage to growth structures and/or host substrates, while also timely achieving a uniform bond.

FIG. 1a shows a non-limiting example of an appropriate growth structure 12 and host substrate 26 having first metal layer 28 and second metal layer 30, respectively, for performing the processes disclosed herein. Growth structure 12 comprises a wafer 14 having a growth surface 16, a sacrificial layer 18, and a device region 20. The device region 20 includes a surface 24 furthest from the wafer 14. The sacrificial layer 18 is disposed between the wafer 14 and the device region 20.

The growth structure 12 may optionally contain one or more protection layers disposed between the wafer 14 and the sacrificial layer 18. Growth structure 12 may also optionally include one or more protection layers between the sacrificial layer 18 and the device region 20. The protection layers serve to protect the wafer and/or the device region, respectively, during the ELO process, which requires etching of the sacrificial layer. U.S. Pat. No. 8,378,385 and U.S. Patent Application Publication No. US 2013/0043214 are incorporated herein by reference for their disclosure of growth structures and protection layer schemes for protecting wafers and device regions during ELO.

The growth structure 12 may further optionally comprise one or more strained layers disposed between the wafer and the device region 20. In some embodiments, the one or more strained layers are disposed between the wafer and the sacrificial layer 18. In some embodiments, the one or more strained layers are disposed between the sacrificial layer and the device region. The one or more strained layers may assist in releasing the device region from the wafer during, e.g., ELO or during a combination of ELO and spalling as described in International Application No. PCT/US2014/052642. PCT/US2014/052642 is hereby incorporated by reference for its disclosure of one or more strained layers.

The growth structure 12 may further include one or more buffer layers as desired.

Wafer 14 may comprise any number of materials, including single-crystal wafer materials. In some embodiments, the wafer may comprise a material chosen from Germanium (Ge), Si, GaAs, InP, GaP, GaN, GaSb, AlN, SiC, CdTe, sapphire, and combinations thereof. In some embodiments, the wafer comprises GaAs. In some embodiments, the wafer comprises InP. In some embodiments, the materials comprising the wafer may be doped. Suitable dopants may include, but are not limited to, Zinc (Zn), Mg (and other group IIA compounds), Zn, Cd, Hg, C, Si, Ge, Sn, O, S, Se, Te, Fe, and Cr. For example, the wafer may comprise InP doped with Zn and/or S. Unless otherwise indicated, it should be understood that reference to a layer comprising, e.g., InP encompasses InP in its undoped and doped (e.g., p-InP, n-InP) forms. Suitable dopant selections may depend, for example, on the semi-insulating nature of a substrate, or any defects present therein.

The sacrificial layer 18 of the growth structure acts as a release layer during, e.g., the ELO process or during a combination of ELO and spalling techniques (See PCT/US2014/052642 incorporated herein by reference for its disclosure of techniques combining ELO and spalling to separate a device region from a parent wafer). The sacrificial layer may be lattice matched or mismatched to the device region. The sacrificial layer may be chosen to have a high etch selectivity relative to the device region and/or the wafer such that the sacrificial layer may be etched while minimizing or eliminating etching of the device region and/or wafer. In some embodiments, the sacrificial layer comprises a III-V material. In some embodiments, the III-V material is chosen from AlAs, AlInP, and AlGaInP. In certain embodiments, the sacrificial layer comprises AlAs. In some embodiments, the sacrificial layer has a thickness in a range from about 2 nm to about 200 nm, such as from about 4 nm to about 100 nm, from about 4 nm to about 80 nm, or from about 4 nm to about 25 nm.

As used herein, the “device region” refers to a region comprising one or more thin-film layers suitable for use in any electronic or optoelectronic device. In some embodiments, the device region refers to a region comprising one or more crystalline, polycrystalline, or amorphous semiconductor materials, such as silicon, gallium arsenide, cadmium telluride, etc. In some embodiments, the device region comprises at least one photoconductive layer. In certain embodiments, the at least one photoconductive layer comprises a III-V material. In certain embodiments, the device region comprises suitable highly doped p-type and n-type semiconductor materials. Suitable semiconductor materials include but are not limited to III-V materials, such as GaAs and indium gallium phosphide (InGaP).

In some embodiments, the host substrate 26 is plastic, such as a flexible plastic. In certain embodiments, the host substrate comprises a polymer material. Suitable flexible host substrate materials may include but are not limited to polyimide films, such as poly-oxydiphenylene-pyromellitimide (Kapton). One of ordinary skill in the art will appreciate that the host substrate may comprise any suitable polymer material or blend of polymer materials for use as a substrate for a thin-film electronic or optoelectronic device.

In other embodiments, the host substrate 26 comprises a metal foil, such as a flexible metal foil. In one embodiment, the metal foil comprises Cu. In another embodiment, the metal foil comprises Al. One of ordinary skill in the art, however, will appreciate that the host substrate 26 may comprise any metal foil suitable for use as a substrate for a thin-film electronic or optoelectronic device.

In some embodiments, a diffusion barrier can be applied to the host substrate, such as a copper foil host substrate, to prevent diffusion between the host substrate material and a material of an adjacent layer, such as the second metal layer, during the disclosed thermally-assisted cold-weld bonding process.

In some embodiments, the first and second metal layers 28 and 30 comprise noble metals. The first and second metal layers may comprise the same or different noble metals. Examples of suitable noble metals may include but are not limited to gold (Au), platinum (Pt), iridium (Ir), palladium (Pd), silver (Ag), rhodium (Rh), ruthenium (Ru), and copper (Cu). In certain embodiments, the first and second metal layers comprise gold. In certain embodiments, the first and second metal layers comprise copper.

In some embodiments, one or more additional metal layers, as shown in FIG. 1b, are deposited on the surface of the device region before depositing the first metal layer 28. The one or more additional metal layers may form an ohmic contact with a semiconductor layer of the device region. Examples of the one or more metal layers include layers of Pd, Ge, and Au.

FIG. 2 shows a non-limiting example of a thermally-assisted cold-weld bonding process (200). The process 200 may be used for attaching the growth structure 12 to the host substrate 26 by bonding the first metal layer 28 and the second metal layer 30 according to FIGS. 1a-b. The process 200 includes providing a growth structure (step 202), wherein the growth structure, as described above, comprises a wafer having a growing surface, a sacrificial layer, and a device region, wherein the sacrificial layer is disposed between the wafer and the device region, and wherein the device region has a surface furthest from the wafer.

The step of providing a growth structure may comprise depositing the sacrificial layer on the growing surface of the wafer and depositing the device region on the sacrificial layer. In embodiments where the growth structure comprises one or more protection layers, one or more straining layers, and/or one or more buffer layers, the process may further comprise depositing one or more protection layers, one or more straining layers, and/or one or more buffer layers (1) on the growing surface of the wafer before depositing the sacrificial layer; and/or (2) on the sacrificial layer before depositing the device region.

Process 200 also comprises providing a host substrate (step 204). As described above, in some embodiments, the host substrate comprises a polymer material. In some embodiments, the host substrate is a plastic. In other embodiments, the host substrate is a metal foil.

Process 200 also comprises depositing a first metal layer on the surface of the device region (step 206) and depositing a second metal layer on the host substrate (step 208). To the extent that the growth structure includes one or more additional layers over the device region that are considered not part of the device region, it should be apparent from the present disclosure that “depositing a first metal layer on the surface of the device region” includes depositing the first metal layer on the last layer that is deposited over the device region (i.e., the layer furthest from the wafer).

Similarly, to the extent the host substrate includes additional layers, such as one or more straining layers (e.g., an iridium layer), it should be understood that “depositing the second metal layer on the host substrate” includes depositing the second metal layer on the surface of one of the additional layers (see, e.g., FIG. 3). An Ir straining layer, for example, deposited on the host substrate can add strain to the host substrate, significantly reducing the time to separate the device region from the wafer during ELO. International Application Publication No. WO 2013/184638 is incorporated by reference for its disclosure of straining layers suitable for assisting ELO.

Process 200 also comprises bonding the first metal layer to the second metal layer (step 210) by pressing the first and second metal layers together at a bonding temperature T_{Bond}, wherein the bonding temperature T_{Bond} is above room temperature T_{Room} and below a failure temperature T_{Fail} of the host substrate.

In embodiments where the host substrate comprises a polymer material, the failure temperature T_{Fail} is the lower of a glass transition temperature of the host substrate and a melting temperature of the host substrate. In some embodiments where the host substrate comprises a polymer material, the bonding temperature T_{Bond} is greater than room temperature, such as, for example, a temperature within the range of 30°-350° C., 60°-340° C., 80°-330° C., 100°-320° C., 110°-310° C., 120°-300° C., 130°-290° C., 140°-280° C., 150°-270° C., 160°-260° C., 170°-250° C., 180°-240° C., 190°-230° C., 190°-220° C., or 190°-210° C.

In embodiments where the host substrate comprises a metal foil, the failure temperature T_{Fail} may be a melting temperature of the host substrate. In some embodiments where the host substrate comprises a metal foil, T_{Fail} is the lower of a melting temperature of the host substrate and 650° C. In certain embodiments where the host substrate comprises a metal foil, T_{Fail} is less than 600° C., such as, less than 550° C., less than 500° C., less than 450° C., less than 400° C., less than 350° C., less than 300° C., less than 290° C., less than 280° C., less than 270° C., less than 260° C., less than 250° C., less than 240° C., less than 230° C., less than 220° C., less than 210° C., less than 200° C., less than 190° C., or less than 180° C. In certain embodiments where the host substrate comprises a metal foil, the bonding temperature may be above 30° C., such as, for example, above 40° C., above 50° C., above 60° C., above 70° C., above 80° C., above 90° C., above 100° C., above 110° C., above 120° C., above 130° C., above 140° C., or above 150° C.

In some embodiments, both the first and second metal layers comprise gold and the bonding temperature T_{Bond} is a temperature within the range of 30°-280° C., such as 40°-280° C., 50°-280° C., 60°-270° C., 70°-260° C., 80°-250° C., 90°-250° C., 100°-250° C., 110°-250° C., 120°-250° C., 130°-250° C., 140°-250° C., 150°-250° C., 160°-250° C., 170°-250° C., 180°-230° C., or 190°-210° C.

In some embodiments, both the first and second metal layers comprise copper and the bonding temperature T_{Bond} is a temperature within the range of 30°-350° C., 60°-340° C., 80°-330° C., 100°-320° C., 110°-310° C., 120°-300° C., 130°-290° C., 140°-280° C., 150°-270° C., 160°-260° C., 170°-250° C., 180°-240° C., 190°-230° C., 190°-220° C., or 190°-210° C.

It should be understood that the bonding temperature is permitted to vary so long as it meets the criteria of the present disclosure, such as, for example, staying within a disclosed range for the bonding temperature.

In some embodiments the first and second metal layers are pressed together with a bonding pressure below 200 MPa, such as, below 175 MPa, below 150 MPa, below 125 MPa, below 100 MPa, below 90 MPa, below 80 MPa, below 70 MPa, below 60 MPa, below 50 MPa, below 40 MPa, below 30 MPa, below 20 MPa, below 10 MPa, below 8 MPa, below 6 MPa, below 4 MPa, below 2 MPa, or below 1 MPa. In some embodiments, the bonding pressure is a pressure within the range of 0.25 MPa-100 MPa, such as, for example, within 0.5 MP-80 MPa, within 1 MPa-60 MPa, within 1 MPa-40 MPa, within 1 MPa-20 MPa, within 1 MPa-10 MPa, within 1 MPa-8 MPa, within 2 MPa-6 MPa, or within 2 MPa-4 MPa.

In some embodiments an amount of time during which the first and second metal layers are pressed together at the bonding temperature and the bonding pressure is less than 20 minutes, such as, for example, less than 15 minutes, less than 10 minutes, less than 8 minutes, less than 6 minutes, less than 5 minutes, less than 4 minutes, less than 3 minutes, less than 2 minutes, less than 1 minute, less than 45 seconds, less than 30 seconds, less than 20 seconds, less than 15 seconds, less than 10 seconds, less than 5 seconds, or less than 3 seconds. In certain embodiments, an amount of time during which the first and second metal layers are pressed together at the bonding temperature and the bonding pressure is a time within the range of 1 second-20 minutes, such as, within 1 second-15 minutes, within 1 second-10 minutes, within 10 seconds-10 minutes, within 30 seconds-10 minutes, within 45 seconds-10 minutes, within 1 minute-10 minutes, within 1 minute-8 minutes, within 1 minute-6 minutes, within 1 minute-5 minutes, or within 2 minutes-4 minutes.

In some embodiments the bonding occurs under vacuum, such as, for example, at 10⁻⁵ Torr, 10⁻⁴ Torr, 10⁻³ Torr, 10⁻² Torr, or 10⁻¹ Torr.

The methods of the present disclosure may further comprise performing an ELO process or an ELO process in combination with spalling as described herein. For example, after performing thermally-assisted cold-weld bonding to attach the growth structure to the host substrate via the first and second metal layers, the process may further comprise releasing the device region from the wafer via ELO or a combination of ELO and spalling. In some embodiments, the device region is removed from the wafer by etching the sacrificial layer. In certain embodiments, the sacrificial layer is etched with a chemical etchant. In certain embodiments, the sacrificial layer is AlAs and the chemical etchant is HF.

In embodiments using protection layers, the protection layers may then be removed by etching. The growing surface of the wafer is thereby preserve for reuse.

In some embodiments, the device region comprises one or more layers suitable for use in a photovoltaic device.

The devices and methods described herein will be further described by the following non-limiting examples, which are intended to be purely exemplary.

### EXAMPLES

FIG. 3 shows an exemplary configuration according to a specific embodiment of the disclosed process. A growth structure was provided, wherein the growth structure included a wafer having a growing surface, a device region, and a sacrificial layer disposed between the device region and the wafer. A Kapton sheet was provided as the host substrate. An optional 10 nm thick Ir adhesion straining layer was sputtered on the Kapton sheet. The optional Ir layer provides tensile strain to the substrate that reduces the wafer and host substrate separation time during the ELO process. A 350 nm thick Au layer was deposited on the host substrate (constituting the second metal layer) and on the surface of the device region (constituting the first metal layer) of the growth structure.

Thermally-assisted cold-weld bonding was performed under vacuum at 10⁻⁵ Torr with an applied force yielding a bonding pressure of 4 MPa. Bonding was performed at a bonding temperature of 175° C., which is a temperature above room temperature and below the glass transition temperature of the Kapton sheet. The process allowed for a 92% reduction in bonding pressure in comparison to conventional room temperature cold-welding under ambient conditions that operate at about 50 MPa.

Au was selected for both metal layers to utilize the several advantageous properties of Au in the application of bonding thin-film electronic devices. Au is chemically robust to hydrofluoric acid, which can be used to separate the wafer from the device region during ELO processing. Au also conveniently acts as a back contact if either deposited directly on a highly doped n or p type semiconductor layer or combined with appropriate metal at the interface to form a metal alloy (see FIG. 1b). Having high reflectance near the infrared wavelength region, Au can be employed as a rear side mirror, which improves the performance of optoelectronic devices by recycling the photons that reflect off device layers. Further, Au can be combined with strained materials, such as Ir, Ni, and NiFe, to expedite the ELO process. Au is also insensitive to oxidation that can increase the pressure needed to effectively cold-weld metal layers together.

FIG. 4 shows a graph of the force, pressure, and temperature profiles with respect to time that were used with the above example. FIG. 4 shows that under the thermally-assisted cold-weld bonding conditions described above, a bonding time of 3 minutes under the bonding pressure and bonding temperature was used. This short amount of time shows an improvement over typical cold-weld processes that may have bonding times of 20-45 minutes.

It will be apparent to those skilled in the art that various modifications and variations can be made to the disclosed process. Other embodiments will be apparent to those skilled in the art from consideration of the specification and practice of the disclosed process. It is intended that the specification and examples be considered as exemplary only, with a true scope being indicated by the following claims and their equivalents.

What is claimed is:

1. A process for assembling a thin-film optoelectronic device comprising:
providing a growth structure comprising a wafer having a growing surface, a sacrificial layer, and a device region, wherein the sacrificial layer is disposed between the wafer and the device region, and wherein the device region has a surface furthest from the wafer;
providing a host substrate, wherein the host substrate comprises a polymer material;
depositing a first metal layer on the surface of the device region;
depositing a second metal layer on the host substrate;
bonding the first metal layer to the second metal layer by pressing the first and second metal layers together at a bonding temperature, wherein the bonding temperature is above room temperature and below the lower of a glass transition temperature of the host substrate and a melting temperature of the host substrate.

2. The process of claim 1, wherein the bonding temperature is a temperature within the range of 170°-250° C.

3. The process of claim 1 wherein the polymer material comprises a polyimide film.

4. The process of claim 1, wherein the bonding is performed under vacuum.

5. The process of claim 1, wherein the first and second metal layers are pressed together at a bonding pressure within 1 MPa and 40 MPa.

6. The process of claim 1, wherein the first and second metal layers independently comprise a noble metal.

7. The process of claim 1, wherein the first and second metal layers comprise the same noble metal.

8. The process of claim 7, wherein the noble metal is chosen from Au and Cu.

9. The process of claim 8, wherein the noble metal is Au and the bonding temperature is a temperature within the range of 50°-280° C.

10. The process of claim 1 wherein the first and second metal layers are pressed together for a time within the range of 1 second-20 minutes.

11. A process for assembling a thin-film optoelectronic device comprising:
providing a growth structure comprising a wafer having a growing surface, a sacrificial layer, and a device region, wherein the sacrificial layer is disposed between the wafer and the device region, and wherein the device region has a surface furthest from the wafer;
providing a host substrate, wherein the host substrate comprises a metal foil;
depositing a first metal layer on the surface of the device region;
depositing a second metal layer on the host substrate;
bonding the first metal layer to the second metal layer by pressing the first and second metal layers together at a bonding temperature, wherein the bonding temperature is above room temperature and below the lower of a melting temperature of the host substrate and 500° C.

12. The process of claim 11, wherein the bonding temperature is above 150° C. and less than 270° C.

13. The process of claim 11, wherein the bonding is performed under vacuum.

14. The process of claim 11, wherein the first and second metal layers are pressed together at a bonding pressure within 1 MPa and 40 MPa.

15. The process of claim 11, wherein the first and second metal layers independently comprise a noble metal.

16. The process of claim 11, wherein the first and second metal layers comprise the same noble metal.

17. The process of claim 16, wherein the noble metal is chosen from Au and Cu.

18. The process of claim 17, wherein the noble metal is Au and the bonding temperature is a temperature within the range of 50°-280° C.

19. The process of claim 11, wherein the first and second metal layers are pressed together for a time within the range of 1 second-20 minutes.
